(19) United States
(12) Patent Application Publication
(10) Pub. No.: US 2026/0235655 A1
(43) Pub. Date: Aug. 13, 2026

(54) Open load diagnosis by an electrical system comprising an electronic control unit connected to a load which includes a capacitor

(71) Applicant: SCHAEFFLER TECHNOLOGIES AG & CO. KG, Herzogenaurach (DE)

(72) Inventors: Sébastien DAZA, Saint-Lys (FR); Jacques ROCHER, Saint-Orens de Gameville (FR)

(73) Assignee: SCHAEFFLER TECHNOLOGIES AG & CO. KG, Herzogenaurach (DE)

(21) Appl. No.: 19/180,532

(22) Filed: Apr. 16, 2025

(30) Foreign Application Priority Data
Jul. 10, 2024 (FR) FR2407521

(51) Int. Cl. G01R 31/00; G01R 19/12; G01R 19/165; G01R 31/40

(52) U.S. Cl. CPC G01R 31/006; G01R 19/12; G01R 19/16538; G01R 31/40

(57) ABSTRACT

An electrical system including an electronic control unit that includes at least one switch having an output connected on one hand to a load and on the other hand to a current source. The control unit is configured to activate and deactivate the switch and to establish an open load diagnosis by measuring the voltage at the output of the switch after the switch is deactivated. The disclosure also relates to a motor vehicle that includes such an electrical system.

### CROSS REFERENCE TO RELATED APPLICATIONS

This application claims priority to French Application No. FR2407521, filed Jul. 10, 2024, the contents of such application being incorporated by reference herein.

### FIELD OF THE INVENTION

The present description relates to the field of electrical systems, in particular those which are fitted on board motor vehicles. In particular, it deals with an electrical system comprising an electronic control unit that includes at least one switch having an output connected on one hand to a load and on the other hand to a current source. It also relates to a motor vehicle that comprises such an electrical system.

### BACKGROUND OF THE INVENTION

An electronic control unit for controlling a load, for example an actuator of a motor vehicle, must be capable of checking its outputs so as to detect any malfunctions (e.g. open load). There are various means for this, particularly integrated output circuits which are configured to perform a voltage measurement at the output of the switch of the electronic control unit (i.e. low-side switch, better known by the acronym LSD, Low Side Driver, or high-side switch, better known by the acronym HSD, High Side Driver) at the end of a short time interval (e.g. 100 μs) after it is deactivated, in order to be able to rapidly diagnose a fault. The measured voltage value is compared to a pre-established threshold value (e.g. 2.2 V), and an open load diagnosis is established if the measured value is greater than the threshold value. This approach makes it possible to effectively and rapidly diagnose an open load when the electronic control unit is connected to a load that contains only coils and resistors. However, this diagnostic method no longer works when the load incorporates a capacitor at input, which is the case in some modern actuators which incorporate such a component, especially in order to attenuate the effects of electrostatic discharges. This is because a capacitor discharges relatively slowly, and if the voltage is measured at the output of the switch after a short time interval following its deactivation, a voltage value is obtained that remains greater than the threshold value, which leads to the creation of an incorrect diagnosis. This problem is illustrated by means of the graph depicted in FIG. 1. As can be seen, due to the slow discharging of the capacitor of the load, the voltage measured at the output of the switch of the electronic control unit after a short time interval (100 μs) following the deactivation of the switch is greater than the threshold value (Vs), which creates an incorrect open load diagnosis.

### SUMMARY OF THE INVENTION

The present description aims to at least partially overcome this drawback. In particular, it has the objective of providing a solution so that an electronic control unit connected to a load that incorporates a capacitor can rapidly diagnose an open load, while minimizing the cost of implementing such a solution.

According to a first aspect, an electrical system is described that comprises an electronic control unit including at least one switch having an output connected to a load. The control unit is configured to activate and deactivate the switch and to establish an open load diagnosis by measuring the voltage at the output of the switch after the switch is deactivated. The input impedance of the load is a capacitor. The switch is connected at input in series with a coil. And the electronic control unit is configured to:
apply to the switch, after it is deactivated, a diagnostic command in the form of a low-duty-cycle pulse width modulation, including several pulses, so as to discharge the capacitor over the duration of the diagnostic command;
establish the open load diagnosis after the last pulse of the diagnostic command.

According to one variant, the duty cycle can be between 5% and 15%.

According to another variant, the duty cycle can be equal to 10%.

According to yet another variant, the diagnostic command can include a number of pulses and the coil can have an inductance value, said number and said value being predefined as a function of the capacitance of the capacitor.

According to yet another variant, since the voltage across the load has a rise time when the switch is activated by an activation command, and the capacitor is likely to recharge during each pulse of the diagnostic command, the number of pulses of the diagnostic command and the inductive value of the coil can be optimized taking into account one or more constraints from among the following constraints:
minimize the recharging of the capacitor during each pulse of the diagnostic command;
minimize the rise time of the voltage across the load at the time of the command to activate the switch;
minimize the number of pulses of the diagnostic command.

According to yet another variant, the diagnostic command can include between 5 and 15 pulses.

According to yet another variant, the diagnostic command can include 10 pulses.

According to yet another variant, the switch can be a high-side switch and the load can be installed between the output of the switch and a low voltage reference point, or the switch can be a high-side switch and the load can be installed between the output of the switch and a high voltage reference point.

According to yet another variant, the inductance of the coil can be between 1 and 50 mH.

According to a second aspect, a motor vehicle is described that comprises an electrical system as defined above.

### BRIEF DESCRIPTION OF THE DRAWINGS

Other features and advantages will become apparent upon examining the following detailed description and the appended figures, in which:

FIG. 1 is a graph that illustrates the problem of diagnosing an open load with a method according to the prior art;

FIG. 2 is a diagram of an exemplary embodiment of an electrical system according to the present description; and

FIG. 3 is a graph that illustrates an open load diagnosis carried out by an electrical system according to the present description.

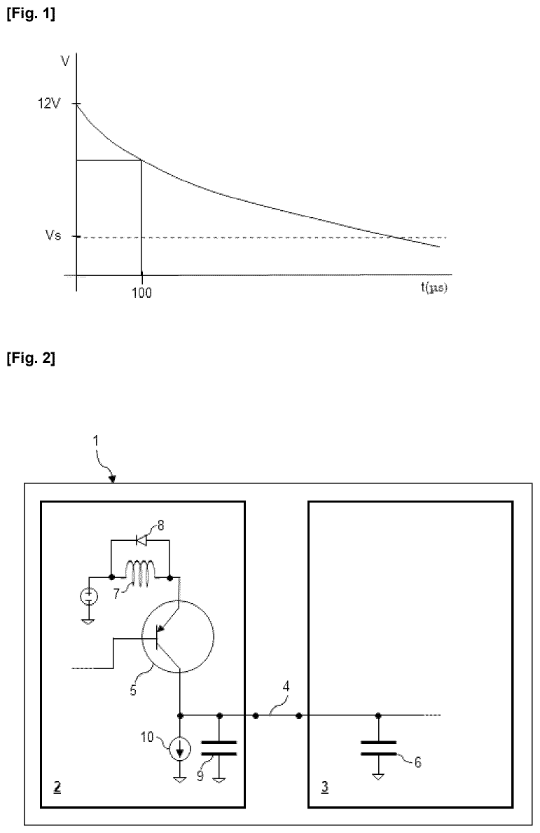

### DETAILED DESCRIPTION

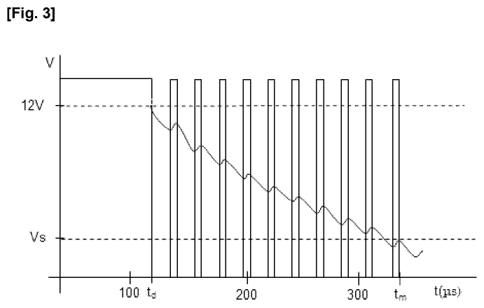

FIG. 2 schematically illustrates an exemplary embodiment of an electrical system 1 according to the present description. The system traditionally includes an electronic control unit 2, referred to below by the acronym ECU, which is connected to a load 3, for example an actuator of a motor vehicle, by means of at least one cable 4. Conventionally, the ECU 2 includes at least one switch 5 which can be, as in the illustrated example, a high-side switch, better known by the acronym HSD, High Side Driver, or a low-side switch, better known by the acronym LSD, Low Side Driver.

The ECU 2 is thus configured to activate and deactivate the switch 5 by means of an ON/OFF signal or, advantageously, by means of a pulse width modulation signal, also known by the acronym PWM. Moreover, as will be presented in detail below, the ECU 2 of the electrical system 1 according to the present description is configured to establish an open load diagnosis by measuring the voltage at the output of the switch 5.

Traditionally, the output of the switch 5 is connected to ground by an output capacitor 9 with a low value, for example a few nanofarads, in particular to attenuate the effects of electrostatic discharge. A current source 10 is also connected between the output of the switch 5 and ground. Its role is to discharge the output capacitor 9 when the switch 5 is open, by pulling the current toward ground. The size of the current source 10 is adapted to that of the capacitor 9.

According to the present description, the input impedance of the load 3 is a capacitor 6, which is used in particular to attenuate the effects of electrostatic discharges. When the switch 5 of the ECU 2 is a high-side switch, as is the case in the illustrated example, the load 3 is installed between the output of the switch 5 and a low voltage reference point. When the switch 5 of the ECU 2 is a high-side switch, as is the case in the illustrated example, the load 3 is installed between the output of the switch 5 and a low voltage reference point.

The capacitance of the load capacitor 6 is generally much larger than that of the output capacitor 9 (in a non-limiting exemplary embodiment, the capacitance of the output capacitor 9 can be 10 nF and the capacitance of the load capacitor 6 can be 110 nF). This means that the current source 10 is not dimensioned to rapidly discharge the load capacitor 6. Therefore, according to the prior art, after the switch 5 is deactivated, the load capacitor 6 is discharged slowly by the resistors of the load 3.

Advantageously, the ECU 2 incorporates a coil 7 connected in series at the input of the switch 5 and, in parallel, with a diode 8, also known by the term free-wheeling diode that is well known to a person skilled in the art. As will be seen further below, the coil 7 advantageously makes it possible to limit the recharging of the capacitor 6 of the load 3 when a particular command is applied to the switch 5, in particular a diagnostic command in the form of a pulse width modulation which, according to the present description, is applied by the ECU 2 to the switch 5 after it is deactivated, so as to discharge the capacitor 6 over the duration of the diagnostic command.

This is because the ECU 2 of the electrical system 1 according to the present description is advantageously configured to apply to the switch 5, after it is deactivated, a diagnostic command in the form of a low-duty-cycle pulse width modulation, including several pulses, so as to discharge the load capacitor 6 over the duration of the diagnostic command, and to establish the open load diagnosis after the last pulse of the diagnostic command.

By virtue of the pulse width modulation signal, the speed of discharging the load capacitor 6 is therefore advantageously maximized. This is because when a capacitor receives a PWM signal, it undergoes repeated charging and discharging cycles as a function of the ON and OFF states of the PWM signal. During the ON (or high) periods, the capacitor charges. During the OFF (or low) periods, the capacitor discharges through the circuit. At each pulse of the diagnostic command PWM signal, the current source 10 pulls current toward ground, which discharges the capacitors 9 and 6. As explained above, the current source is not dimensioned to discharge the capacitor 6. The application of several pulses has the effect of repeating the phenomenon of discharging by the current source 10 and thus allows the discharging time of the load capacitor 6 to be reduced.

Moreover, using a low duty cycle makes it possible to maximize the OFF time of the diagnostic command signal so that the capacitor spends more time discharging and the discharging is more rapid.

According to the present description, the duty cycle is preferably between 5% and 15%, for example equal to 10%. Moreover, the number of pulses of the diagnostic command and the inductance value of the coil 7 are predefined as a function of the capacitance of the capacitor 6 of the load 3. For example, the coil 7 has an inductance value preferably between 1 and 50 mH. And the number of pulses is equal to 10.

More specifically, the voltage across the load 3 has a rise time when the switch 5 is activated by an activation command, and the capacitor 6 is likely to recharge during each pulse of the diagnostic command. The number of pulses of the diagnostic command and the inductive value of the coil 7 are optimized taking into account one or more constraints from among the following constraints: minimize the recharging of the capacitor 6 during each pulse of the diagnostic command, minimize the rise time of the voltage across the load 3 at the time of the command to activate the switch 5 and/or minimize the number of pulses of the diagnostic command. Preferably, the diagnostic command which is applied by the ECU 2 therefore includes between 5 and 15 pulses, for example 10 pulses.

FIG. 3 shows a graph that illustrates the carrying out of an open load diagnosis by the ECU 2 of the electrical system 1 according to the present description. According to the illustrated example, the switch 5 is deactivated at the instant ta. From this instant, the ECU 2 applies a diagnostic command to said switch in the form of a low-duty-cycle pulse width modulation, for example 10%, by periodically repeating several pulses. The discharging of the capacitor 6 then takes place in such a manner that it is possible to measure the voltage at the output of the switch 5 after the tenth pulse, at the instant tₘ, and to obtain at that instant a voltage value that, when the load is correctly connected, is less than the threshold value Vs, which is set at 2.2 V for example. It is at that instant that the ECU 2 can therefore establish the open load diagnosis, concluding in the illustrated case that the load 3 is correctly connected since the measured voltage is less than the threshold value Vs.

It should be noted that the voltage measured at the output of the switch 5 logically rises at the time of each activation of the switch 5. This is because it is the capacitor 6 of the load 3 that recharges during the high periods of the PWM signal. However, these instances of recharging of the capacitor 6 are advantageously limited by virtue of the coil 7 that is connected in series with the switch 5. This is because the coil slows down the current that is passing through it, which causes the charging of the capacitor 6 to slow down and makes it possible to reach the threshold value Vs at the end of a time interval with a duration that remains very low, of the order of 200 μs.

In practice, it is desirable for the ECU 2 to be able to establish an open load diagnosis as rapidly as possible, in other words the aim will be to obtain a number of pulses that is as low as possible to allow the voltage to drop below the threshold value Vs. To do this, it will be taken into account that the higher the inductance of the coil 7, the more the voltage rise will be delayed. Moreover, the capacitance value of the capacitor 6 will also be taken into account, which also constrains the number of pulses to be produced. Similarly, it will be taken into account that the value of the duty cycle constrains the value of the inductance of the coil 7, because the larger the value of the duty cycle, the higher the value of the inductance of the coil 7 must be as well, which increases its cost and, by extension, the cost of manufacturing the electrical system 1 according to the present description. A balance will therefore be sought to set the duty cycle, the value of the number of pulses and the value of the inductance of the coil 7 so as to be able to minimize the recharging of the capacitor during each pulse of the diagnostic command, to minimize the rise time of the voltage across the load 3 at the time of the command to activate the switch 5 and to minimize the number of pulses of the diagnostic command.

Moreover, taking into account the PWM modulation that in fact creates sudden interruptions in the current flowing in the coil 7 at the time of the successive commands to activate and deactivate the switch 5, it should be noted that the diode 8 connected in parallel with the coil 7 advantageously makes it possible to guard against an overvoltage that is irreversibly generated and that is likely to degrade the electronic components of the system 1. This is because such an overvoltage is generated due to the physical impossibility that a current could stop in a coil. Therefore, by virtue of the diode 8, the energy accumulated in the coil 7 will be able to flow through the diode 8, which will allow there to be a gradual reduction in the energy stored in the coil 7.

Consequently, by virtue of the above-described electrical system according to the present description, a solution is provided so that an electronic control unit connected to a load that incorporates a capacitor can rapidly diagnose an open load, while minimizing the cost of implementing such a solution.

1. An electrical system comprising an electronic control unit that includes at least one switch having an output connected on one hand to a load and on the other hand to a current source, the control unit being configured to activate and deactivate the switch and to establish an open load diagnosis by measuring the voltage at the output of the switch after the switch is deactivated, wherein the input impedance of the load is a capacitor, the switch is connected at input in series with a coil, and the electronic control unit is configured to:
apply to the switch, after it is deactivated, a diagnostic command in the form of a low-duty-cycle pulse width modulation, including several pulses, so as to discharge the capacitor over the duration of the diagnostic command;
establish the open load diagnosis after the last pulse of the diagnostic command.

2. The electrical system as claimed in claim 1, wherein the duty cycle is between 5% and 15%.

3. The electrical system as claimed in claim 1, wherein the duty cycle is equal to 10%.

4. The electrical system as claimed in claim 1, wherein the diagnostic command includes a number of pulses and the coil has an inductance value, said number and said value being predefined as a function of the capacitance of the capacitor.

5. The electrical system as claimed in claim 4, wherein, since the voltage across the load has a rise time when the switch is activated by an activation command, and the capacitor is likely to recharge during each pulse of the diagnostic command, the number of pulses of the diagnostic command and the inductive value of the coil are optimized taking into account one or more constraints from among the following constraints:
minimize the recharging of the capacitor during each pulse of the diagnostic command;
minimize the rise time of the voltage across the load at the time of the command to activate the switch;
minimize the number of pulses of the diagnostic command.

6. The electrical system as claimed in claim 1, wherein the diagnostic command includes between 5 and 15 pulses.

7. The electrical system as claimed in claim 1, wherein the diagnostic command includes 10 pulses.

8. The electrical system as claimed in claim 1, wherein the switch is a high-side switch and the load is installed between the output of the switch and a low voltage reference point, or the switch a high-side switch and the load is installed between the output of the switch and a high voltage reference point.

9. The electrical system as claimed claim 1, wherein the inductance of the coil is between 1 and 50 mH.

10. A motor vehicle, comprising an electrical system as claimed in claim 1.
